(19) United States
(12) Patent Application Publication
(10) Pub. No.: US 2009/0075443 A1
(43) Pub. Date: Mar. 19, 2009

(54) METHOD OF FABRICATING FLASH MEMORY

(76) Inventors: Chia-Che Hsu, Taipei County (TW); Rex Young, Hsinchu City (TW); Pin-Yao Wang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/963,866

(22) Filed: Dec. 24, 2007

(30) Foreign Application Priority Data
Sep. 13, 2007 (TW) 096134244

(51) Int. Cl. H01L 21/8247

(52) U.S. Cl. 438/259; 257/E21.68

(57) ABSTRACT

A method of fabricating a flash memory includes providing a substrate with a mask layer thereon, forming pluralities of shallow trenches in the substrate, forming a first oxide layer on the substrate and in the shallow trenches, removing a portion of the first oxide layer above the mask layer, forming a second oxide layer on the mask layer and the first oxide layer, wherein the first and second oxide layers have different etching ratios, removing a portion of the second oxide layer positioned above the mask layer so that an STI is formed with the first and the second oxide layers in each shallow trench, removing the mask layer to form recess portions between adjacent STIs, and filling the recess portions with a conductive layer to form floating gates in the recess portions.

### BACKGROUND OF THE INVENTION

1. Field of the Invention

The present invention relates to a method of fabricating flash memory, and more particularly, to a method of fabricating flash memory with increased coupling ratio of gates.

2. Description of the Prior Art

Because a flash memory is rewritable and has qualities as fast transfer and low power consumption, it has been widely applied to products of various fields and become a critical device of many information, communication, and consuming electronic products. In order to provide light electronic products with high quality, it has become important for the current information industry and memory manufacturers to increase the device integration and quality of the flash memory.

Conventionally, shallow trench isolations (STIs) are utilized for isolating adjacent memory cells in a flash memory. However, since the integration of the memory cells of a flash memory becomes greater and greater, the traditional formation method of STIs and the quality thereof both meet choke point because the STIs formed according to the conventional method cannot effectively isolate adjacent memory cells, resulting in circuit short or current leakage to influence the operation performance of the flash memory. Please refer to FIGS. 1-6, which are schematic diagrams of fabricating a flash memory 10 according to the prior art. First, as shown in FIG. 1, a silicon substrate 12 is provided, and a thin oxide layer 14, a first polysilicon layer 16, and a mask layer 18 are successively formed on the silicon substrate 12. Then, a photolithography-etching process is performed to remove portions of the mask layer 18, the first polysilicon layer 16, the oxide layer 14, and the silicon substrate 12 to form pluralities of shallow trenches 20 on the surface of the silicon substrate 12.

Sequently, as shown in FIG. 2, a liner 22 is formed on the surfaces of the shallow trenches 20, and a high-density plasma (HDP) deposition process is carried out to form a HDP oxide layer 24 on the silicon substrate 12, which fills the shallow trenches 20 and serves as an isolation material to form shallow trench isolations (STIs). However, the currently formed flash memory 1 0 has a high integration, which means the aspect ratio of the shallow trenches 20 is high, and the gap-fill ability of the oxide material formed by the HDP deposition process is poor. Accordingly, the HDP oxide layer 24 cannot completely fill the shallow trenches 20, and voids 26 are easily formed in the upper portions of the shallow trenches 20, as shown in FIG. 2. After the HDP deposition process is performed, a sintering process is performed for densifying the HDP oxide layer 24.

Next, as shown in FIG. 3, a polishing process is carried out to remove a portion of the HDP oxide layer 24 positioned above the surface of the mask layer 18, exposing the voids 26. Referring to FIG. 4, then, the mask layer 18 is removed so that the top surface of the HDP oxide layer 24 is higher than the top surface of the first polysilicon layer 16 and the surface of the silicon substrate 12 to complete the fabrication of STIs 28. Since the mask layer 18 above of the silicon substrate 12 is removed, pluralities of recess portions 30 are formed between adjacent STIs 28.

With reference to FIG. 5, a second polysilicon layer 32 is deposited on the silicon substrate 12. The second polysilicon layer 32 covers the first polysilicon layer 16 and the STIs 28, and fills the recess portions 30 and the voids 26. Sequentially, as shown in FIG. 6, the STIs 28 are taking as a polishing-stop layer to perform a chemical mechanical polishing (CMP) process for removing the second polysilicon layer 32 that is positioned above the top surface of the STIs 28. Accordingly, the remaining second polysilicon layer 32 and the first polysilicon layer 16 in the recess portions 30 together form floating gates 34. However, since the second polysilicon layer 32 still remains in the voids 26 and which is quite near the floating gates 34, lateral current leakage or active area short easily occurs between the adjacent floating gates 34 and the second polysilicon layer 32 disposed in the voids 26, seriously influencing the operation efficiency and stability of the flash memory 10.

Accordingly, how to improve current fabrication method and structure of flash memory to provide flash memories with good operation performance and high stability is still an important issue for the manufacturers.

### SUMMARY OF THE INVENTION

It is a primary objective of the claimed invention to provide a fabrication method of flash memory that at least two oxide layers with different etching ratios are utilized to fill the shallow trenches so as to solve the above-mentioned problems of current leakage and active area short occurring in the flash memory according to the prior-art fabrication method.

According to the claimed invention, a method of fabrication a flash memory is provided, and the method comprises: providing a substrate having a mask layer thereon; removing portions of the mask layer and the substrate to form a plurality of shallow trenches; forming a first oxide layer on the substrate to fill the shallow trenches; removing a portion of the first oxide layer positioned above the mask layer; forming a second oxide layer on the first oxide layer and the mask layer, wherein the second oxide layer has an etching ratio different from the etching ratio of the first oxide layer; removing a portion of the second oxide layer above the mask layer so that the remaining first and second oxide layers form a STI in each shallow trench; removing the mask layer to form recess portions between adjacent STIs; and filling the recess portions with a first conductive layer to form a floating gate in each of the recess portions.

It is an advantage of the claimed invention that the second oxide layer is formed to fill the voids in the first oxide layer so as to prevent the sequentially formed polysilicon layer or other conductive materials from filling the voids, which easily results in current leakage and active area short. As a result, the quality and stability of the flash memory can be improved according to the claimed invention method.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 are schematic diagrams of fabricating a flash memory according to the prior art.

FIGS. 7-16 are schematic diagrams of the fabrication method of a flash memory according to the present invention.

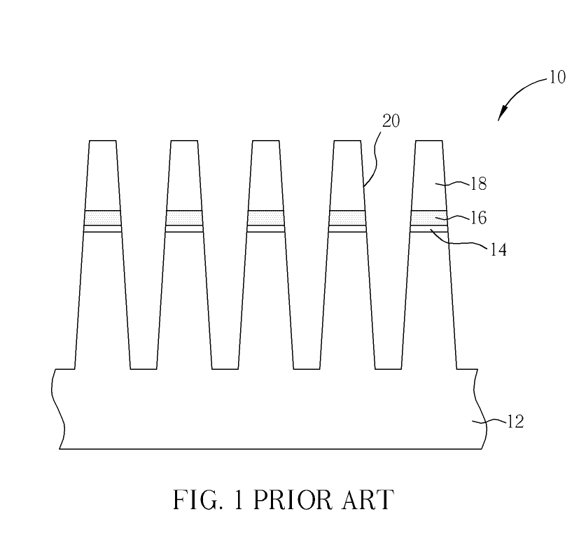

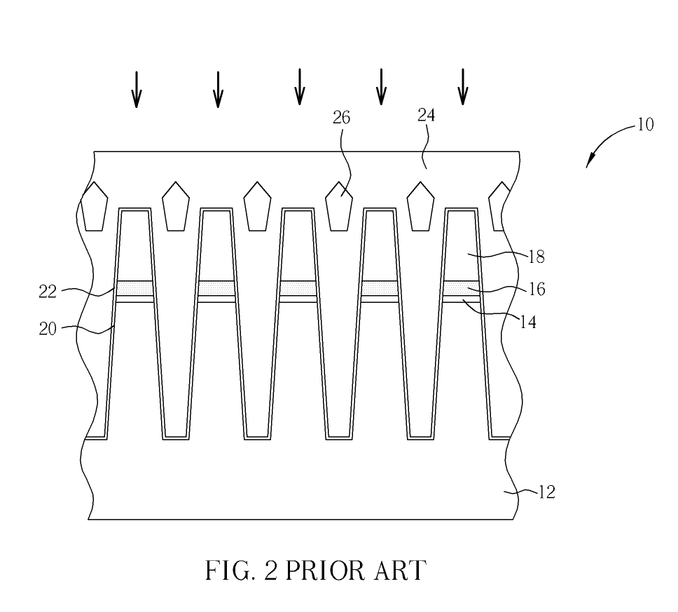

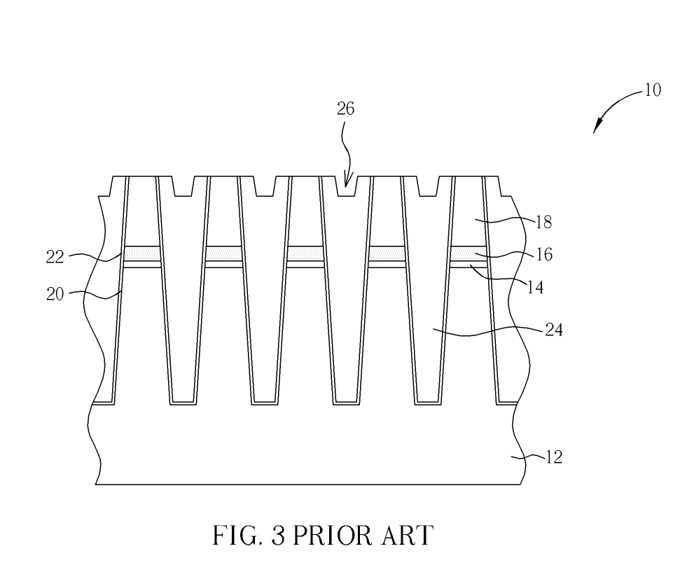

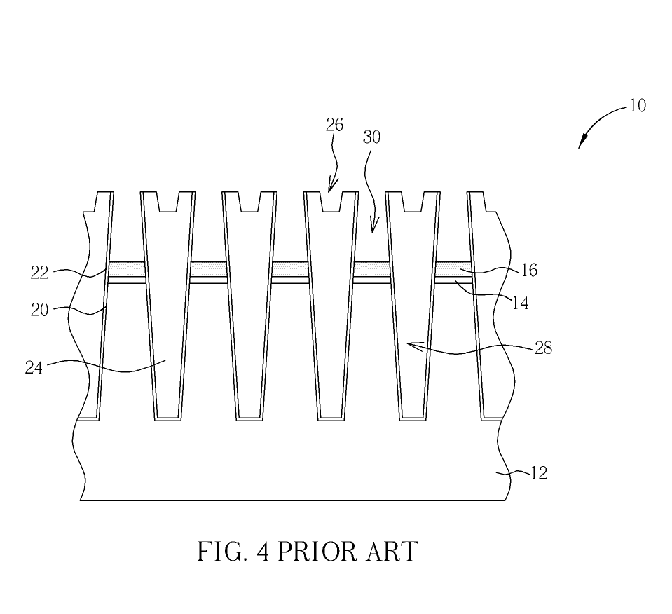

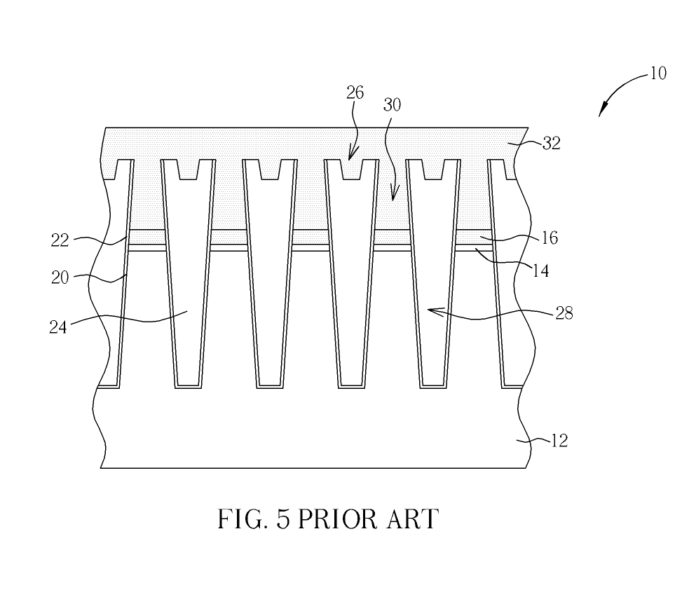

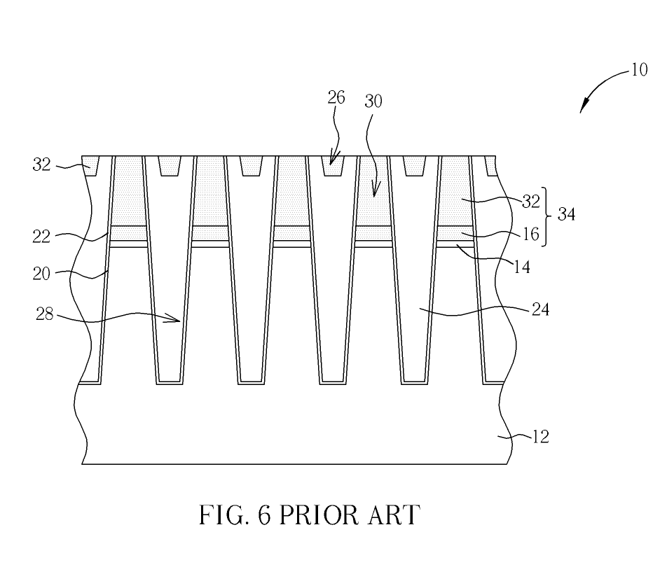

### DETAILED DESCRIPTION

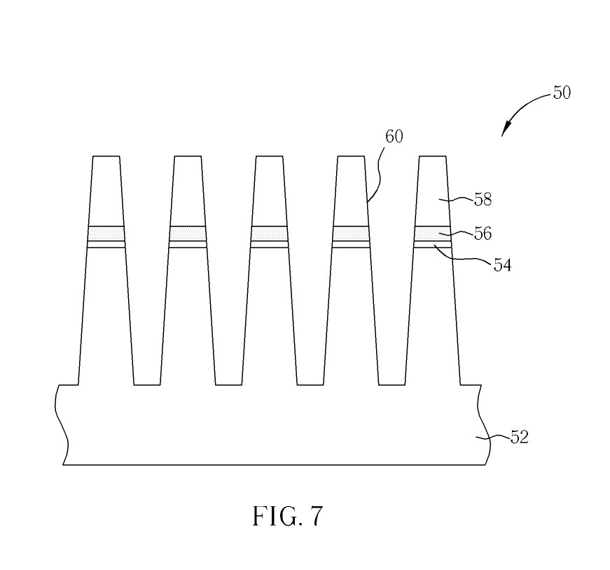

Please refer to FIGS. 7-16, which are schematic process diagrams of the fabrication method of a flash memory 50 according to the present invention. First, as shown in FIG. 7, a semiconductor substrate 52 is provided, which may be a silicon substrate. The semiconductor substrate 52 has a floating gate insulating layer 54, a polysilicon layer 56, and a mask layer 58 thereon, wherein the floating gate insulating layer 54 is a thin oxide layer and the mask layer 58 may comprise silicon nitride materials. Then, a photolithography-etching process is performed to remove partial materials on the surface of the semiconductor substrate 52, such as portions of the mask layer 58, the polysilicon layer 56, the floating gate insulating layer 54, and the semiconductor substrate 52 to form a plurality of shallow trenches 60 in the semiconductor substrate 52. In order to form the flash memory 50 with a high integration, the aspect ratio of the shallow trenches 60 is preferably more than 5.

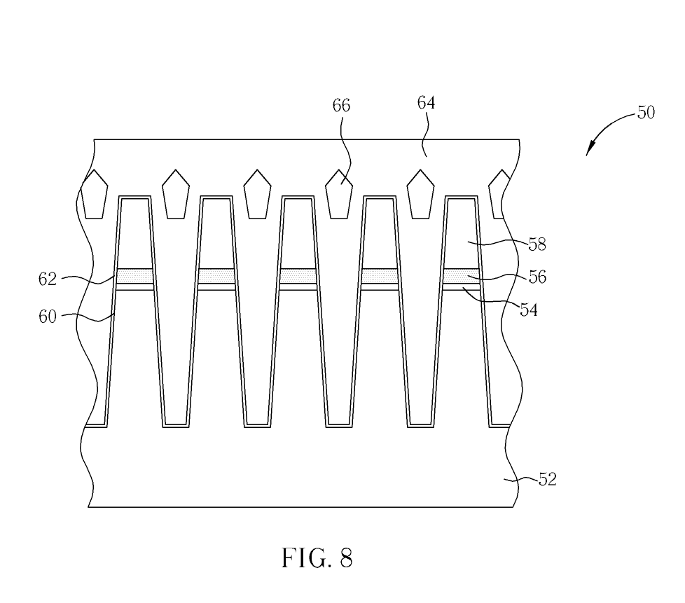

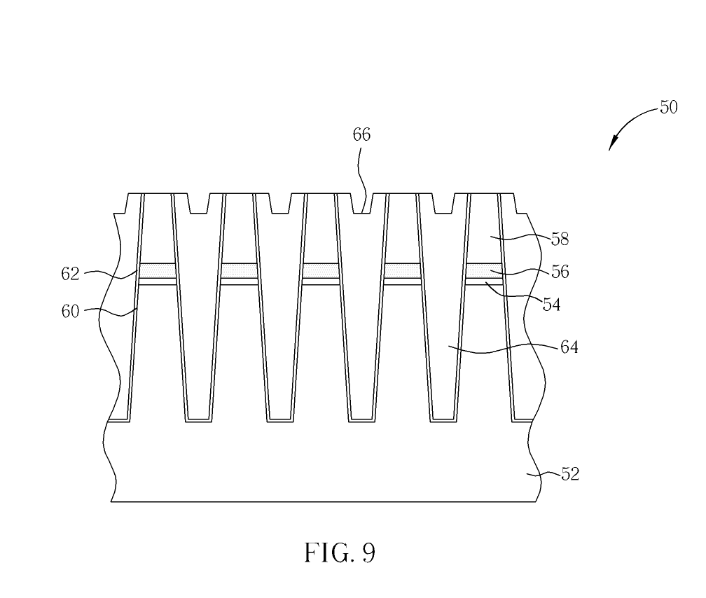

Thereafter, referring to FIG. 8, an oxidization process is performed to form a liner 62 on the surfaces of the shallow trenches 60, and a HDP chemical vapor deposition (CVD) process is performed to form an HDP oxide layer on the surface of the semiconductor substrate 52, represented as the first oxide layer 64 shown in FIG. 8. Since the first oxide layer 64 formed through the HDP deposition process has poor gap-fill ability and the shallow trenches 60 have a high aspect ratio, at least a void 66 is formed within the first oxide layer 64 in the upper portion of each shallow trench 60 while forming the first oxide layer 64 through the HDP deposition process. Then, as shown in FIG. 9, an etching-back process is performed to remove a portion of the first oxide layer 64 and taking the mask layer 58 as an etch stop layer, and therefore the voids 66 in the first oxide layer 64 are exposed.

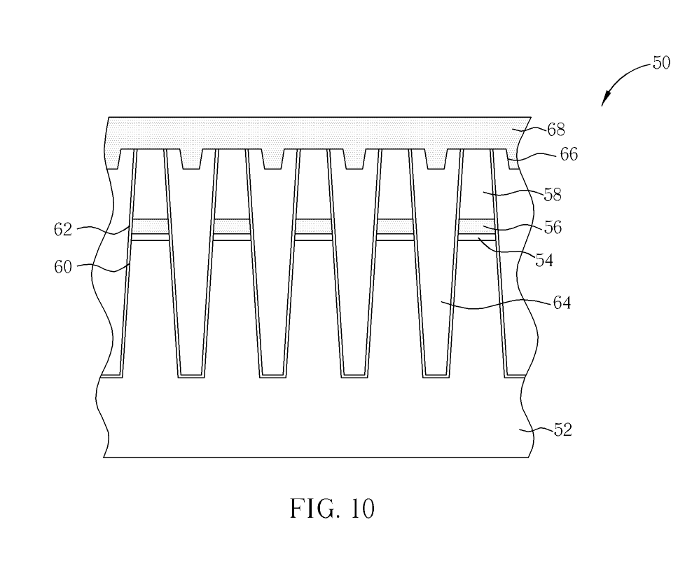

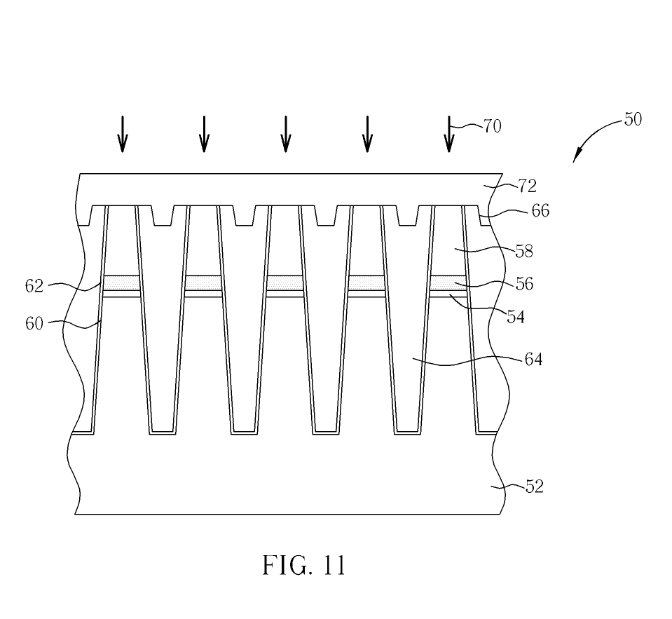

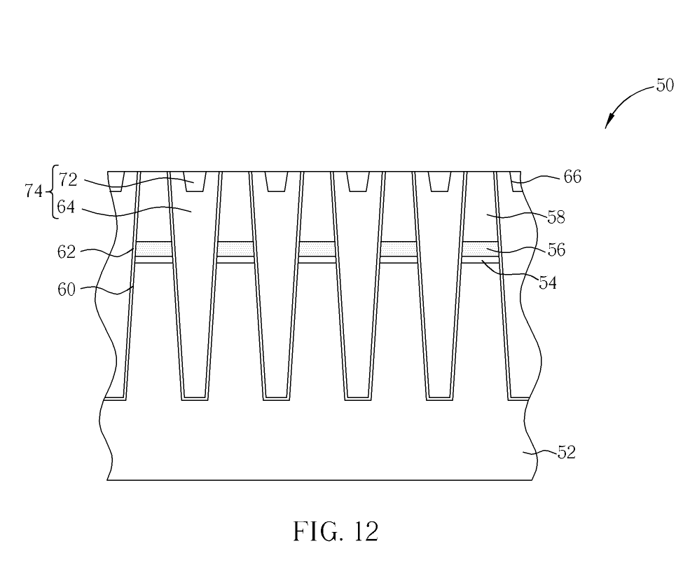

After the voids 66 in the upper portions of the shallow trenches 60 are exposed, a second oxide layer is formed to fill the voids 66. The formation of the second oxide layer is shown in FIG. 10 to FIG. 12. According to a preferable embodiment of the present invention, first, a low-pressure chemical vapor deposition (LPCVD) process is performed to blanket form a polysilicon layer 68 on the surface of the semiconductor substrate 52, filling the exposed voids 66. Sequently, with reference to FIG. 11, a wet-oxidization process 70 is performed in a high-temperature environment to oxidize the polysilicon layer 68 for forming the second oxide layer 72. Thereafter, as shown in FIG. 12, the mask layer 58 is taken as a polishing-stop layer to perform a CMP process for removing a portion of the second oxide layer 72, and the remnant second oxide layer 72 is disposed in the voids 66. After the CMP process, the second oxide layer 72 and the first oxide layer 64 together form STIs 74 in the every shallow trench 60.

It should be noted that the polysilicon layer 68 formed by the LPCVD process has good step coverage ability such that it can effectively fill up the voids 66. In addition, the wet-oxidization process is carried out in a high-temperature environment, and therefore it simultaneously densifies the first oxide layer 64, displacing the sintering process in conventional fabrication methods. Furthermore, because the second oxide layer 72 is formed through oxidizing the polysilicon layer 68 and the first oxide layer 64 is composed of HDP oxide materials, the second oxide layer 72 and the first oxide layer 64 have different etching ratios. In addition, the second oxide layer 72 has preferable thin-film quality so that the flash memory 10 can has good stability.

Although the second oxide layer 72 is fabricated by the way of forming the polysilicon layer 68 and sequentially oxidizing the polysilicon layer 68 in the aforementioned preferable embodiment, the second oxide layer 72 may be fabricated through other processes so as to comprise tetra-ethyl-ortho-silicate (TEOS) or other oxide materials with an etch ratio different from that of the first oxide layer 64. For example, an LPCVD process may be performed by utilizing TEOS as a precursor to fabricate the second oxide layer 72 with TEOS oxide materials.

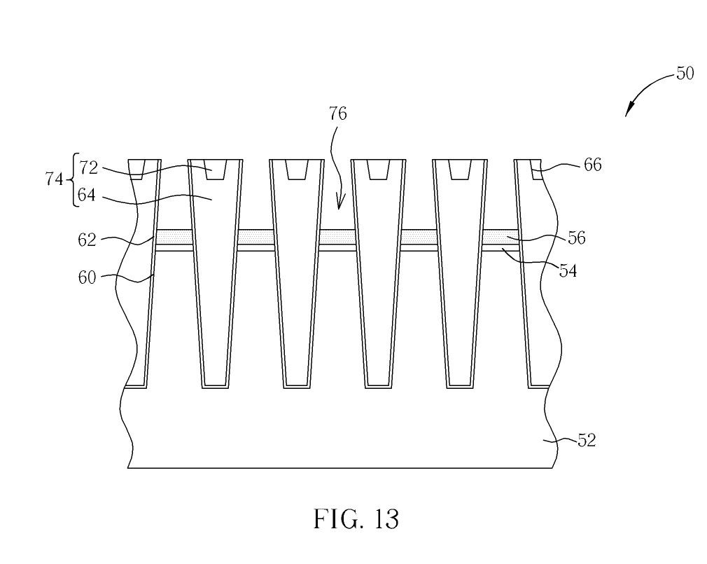

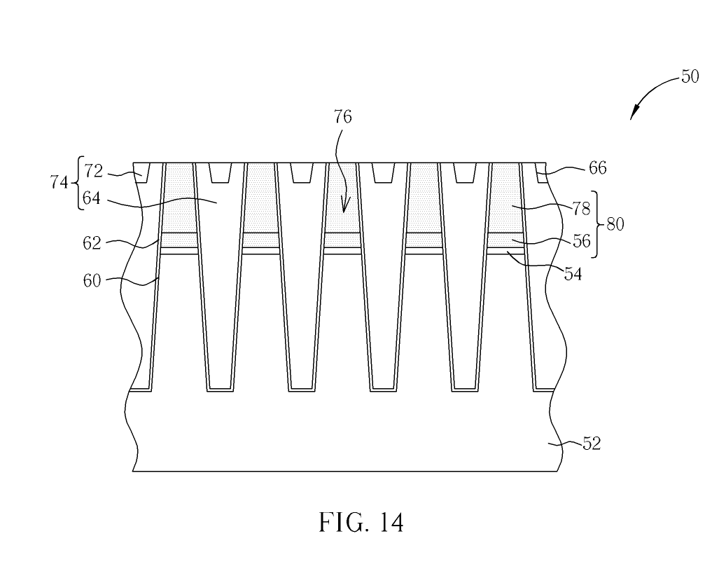

With reference to FIG. 13, after the STIs 74 are fabricated, the mask layer 58 on the semiconductor substrate 52 is removed so as to form a plurality of recess portions 76 between adjacent STIs 74. Then, as shown in FIG. 14, a deposition process is performed to blanket form a first conductive layer 78 on the semiconductor substrate 52, wherein the first conductive layer 78 preferably comprises polysilicon materials. Then, the STIs 74 are taken as a polishing-stop layer to perform a CMP process for removing a portion of the first conductive layer 78 above the STIs 74, and the remaining first conductive layer 78 are disposed in the recess portions 76, forming floating gates 80 together with the polysilicon layer 56.

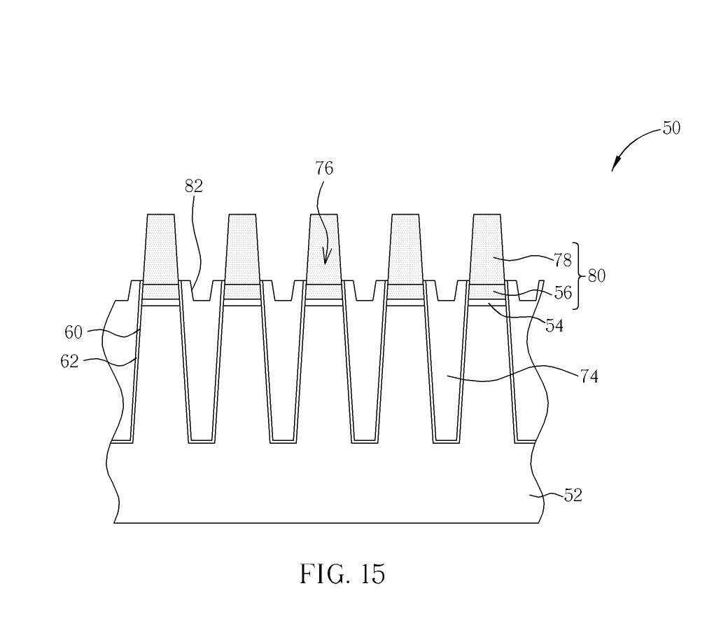

Thereafter, referring to FIG. 15, an etching-back process is performed for the first oxide layer 64 and the second oxide layer 72 disposed in the STIs 74, wherein the etching-back process is preferably a wet-etching process to remove the portions of the first oxide layer 64 and the second oxide layer 72 in the upper portion of the STIs 74. It should be noted that the second oxide layer 72 and the first oxide layer 64 have different etching ratios because they are fabricated by oxidizing polysilicon materials and through an HDP deposition process respectively. As a result, the different etching ratios of the first oxide layer 64 and the second oxide layer 72 influence the etching performance of the etching-back process such that the remnant STIs 74 in the shallow trenches 60 after the etching-back process have step-shaped surfaces 82 with hollow central parts, as shown in FIG. 15, wherein the surfaces 82 of the remnant STIs 74 are similar to the interface surface of the first oxide layer 64 and the second oxide layer 72 before the etching-back process is performed.

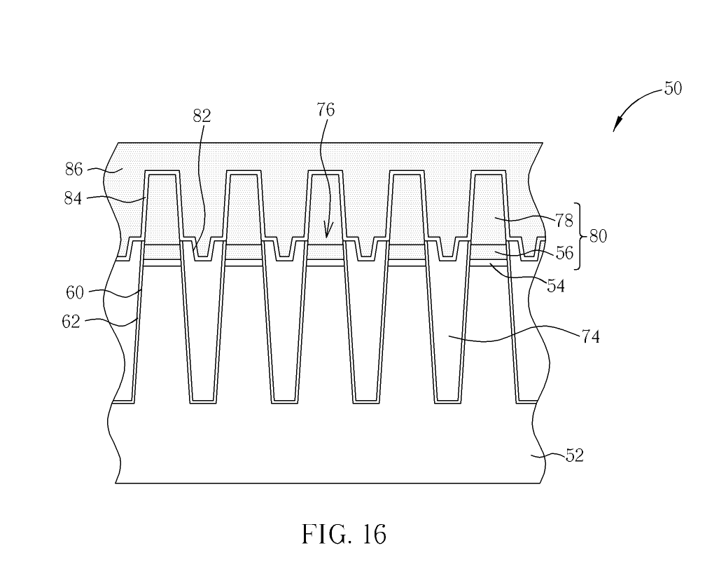

Please refer to FIG. 16. Next, an oxide layer, a nitride layer, and an oxide layer are successively formed on the semiconductor substrate 52 to form a dielectric layer 84, covering the surfaces of the floating gates 80 and the surfaces 82 of the STIs 74. Finally, a deposition process is performed to form a second conductive layer 86 comprising polysilicon materials on the surface of the semiconductor substrate 52. The second conductive layer 86 fills up the upper portions of the shallow trenches 60 and covers the surface of the dielectric layer 84 to form control gates.

As shown in FIG. 16, the dielectric layer 84 conformally covers the surface 82 of the STIs 74, and therefore it has a large coupling area with the floating gates 80, which increases the coupling ratio of the memory cells and effectively improves writing speed of the flash memory 50. Furthermore, according to the fabrication method of the present invention, void defects that may occur in the STIs 74 through traditional formation methods can be avoided, such that the problems of active area short and current leakage existing in the prior art are solved.

In contrast to the prior art that forms HDP oxide layer with poor step-coverage or gap-fill ability in the shallow trenches to fabricate STIs, accounting for voids that causes active area short and current leakage, the present invention fabrication method forms the first and second oxide layers with different etching ratios and qualities in the shallow trenches in sequence to solve the aforementioned problems, so as to increase the stability of the flash memory. In addition, the different etching ratios of the first and second oxide layers influence the performance of the sequentially executed etching-back process to form STIs having surfaces with hollow central parts, which effectively raises the coupling ratios between the control gates and the floating gates to further improve the operation efficiency of the flash memory. Furthermore, according to the present invention, the second oxide layer is formed through depositing a polysilicon layer and oxidizing the polysilicon layer in a high-temperature environment, and therefore the quality of the second oxide layer is preferable, and the high-temperature oxidization process can displace the sintering process for the HDP oxide materials in the prior art to simplify the fabrication process and reduce costs.

Those skilled in the art will readily observe that numerous modifications and alterations of the device and method may be made while retaining the teachings of the invention.

What is claimed is:

1. A method of fabricating a flash memory, comprising: providing a substrate having a mask layer thereon;
removing portions of the mask layer and the substrate to form a plurality of shallow trenches;
forming a first oxide layer on the substrate, the first oxide layer filling the shallow trenches;
removing a portion of the first oxide layer and taking the mask layer as a stop layer;
forming a second oxide layer on the first oxide layer and the mask layer, the second oxide layer having an etching ratio that is different from an etching ratio of the first oxide layer;
removing a portion of the second oxide layer and taking the mask layer as a stop layer, the remaining first and second oxide layers forming a shallow trench isolation (STI) in each of the shallow trenches;
removing the mask layer to form a plurality of recess portions between adjacent STIs;
and
filling the recess portions with a first conductive layer to form a floating gate in each of the recess portions.

2. The method of claim 1, wherein the method further comprises the following steps after forming the floating gates:
performing an etching-back process to remove portions of the STIs to make the remaining STIs have uneven surfaces resulting from the different etching ratios of the first and the second oxide layers;
forming a dielectric layer on the substrate, the dielectric layer covering the floating gates and the surfaces of the STIs; and
forming a second conductive layer on the substrate to cover the dielectric layer.

3. The method of claim 2, wherein each of the remaining STIs has a step-shaped surface after the etching-back process is performed.

4. The method of claim 1, wherein the step of removing the portion of the first oxide layer and taking the mask layer as a stop layer comprises an etching-back process.

5. The method of claim 1, wherein the step of filling the recess portions with the first conductive layer comprises:
forming the first conductive layer on the substrate; and
performing a polishing process by taking the STIs as a polishing-stop layer so as to remove a potion of the first conductive layer and form the floating gates with the remaining first conductive layer recess portions.

6. The method of claim 1, wherein the first oxide layer filling the shallow trenches comprises at least a void positioned in an upper portion of each of the shallow trenches, and the voids are exposed after the portion of the first oxide layer is removed.

7. The method of claim 6, wherein the step of forming the second oxide layer comprises:
forming a polysilicon layer on the substrate and filling the exposed voids;
oxidizing the polysilicon layer to form the second oxide layer; and
performing a polishing process by taking the mask layer as a polishing-stop layer to remove a portion of the second oxide layer.

8. The method of claim 7, wherein the step of oxidizing the polysilicon layer comprises a wet-oxidization process.

9. The method of claim 7, wherein the step of forming the polysilicon layer comprises a low-pressure chemical vapor deposition (LPCVD) process.

10. The method of claim 1, wherein the second oxide layer comprises tetra-ethyl-ortho-silicate (TEOS) oxide materials.

11. The method of claim 10, further comprises performing an LPCVD process to form the second oxide layer.

12. The method of claim 1, wherein the first oxide layer is formed through an HDP deposition process.

13. The method of claim 1, wherein the first conductive layer comprises polysilicon materials.

14. The method of claim 1, wherein the substrate comprises a floating gate insulating layer and a polysilicon layer disposed below the mask layer on the surface of the substrate.

15. The method of claim 14, wherein the polysilicon layer is exposed in the recess portions after the mask layer is removed, and the subsequently formed first conductive layer in the recess portions forms the floating gates together with the polysilicon layer.
